(19) United States
(12) Patent Application Publication
(10) Pub. No.: US 2024/0413271 A1
(43) Pub. Date: Dec. 12, 2024

(54) LUMIPHORIC MATERIALS WITHIN LIGHT-EMITTING DIODE CHIPS

(71) Applicant: CreeLED, Inc., Durham, NC (US)

(72) Inventors: Michael Check, Holly Springs, NC (US); David Suich, Durham, NC (US); Colin Blakely, Raleigh, NC (US); Andre Pertuit, Raleigh, NC (US); Robert Wilcox, Rolesville, NC (US); Joseph G. Sokol, Durham, NC (US)

(21) Appl. No.: 18/330,805

(22) Filed: Jun. 7, 2023

(51) Int. Cl. H01L 33/50; H01L 33/00; H01L 33/10; H01L 33/14; H01L 33/38; H01L 33/44

(52) U.S. Cl. CPC H01L 33/502; H01L 33/0008; H01L 33/10; H01L 33/14; H01L 33/38; H01L 33/44

(57) ABSTRACT

Solid-state lighting devices including light-emitting diodes (LEDs) and more particularly arrangements of lumiphoric materials within LED chips are disclosed. Lumiphoric materials are incorporated or otherwise embedded within LED chips. Embedded lumiphoric materials are provided so that at least some portions of light generated by active LED structures are subject to wavelength conversion before exiting LED chip surfaces. Lumiphoric materials may form dielectric and/or passivation layers between various chip structures, such as between active LED structures and internal reflective layers and/or electrical contacts. Internally converted light propagating within LED chips may pass back through active LED structures with reduced light absorption.

### FIELD OF THE DISCLOSURE

The present disclosure relates to solid-state lighting devices including light-emitting diodes (LEDs) and more particularly to arrangements of lumiphoric materials within LED chips.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions. Lumiphoric materials may be arranged that convert at least some light generated from the active regions of LED chips to a different wavelength.

LED packages have been developed that provide mechanical support, electrical connections, and encapsulation for LED emitters and lumiphoric materials. As LED technology continues to advance, LED packages are needed that emit light of high color quality for various applications. Despite recent advances in LED package technology, challenges remain for producing high quality light with desired emission characteristics while also providing high light emission efficiency in LED packages.

The art continues to seek improved LEDs and solid-state lighting devices having desirable illumination characteristics capable of overcoming challenges associated with conventional LED devices.

### SUMMARY

The present disclosure relates to solid-state lighting devices including light-emitting diodes (LEDs) and more particularly to arrangements of lumiphoric materials within LED chips. Lumiphoric materials are incorporated or otherwise embedded within LED chips. Embedded lumiphoric materials are provided so that at least some portions of light generated by active LED structures are subject to wavelength conversion before exiting LED chip surfaces. Lumiphoric materials may form dielectric and/or passivation layers between various chip structures, such as between active LED structures and internal reflective layers and/or electrical contacts. Internally converted light propagating within LED chips may pass back through active LED structures with reduced light absorption.

In one aspect, an LED chip comprises: an active LED structure comprising an n-type layer, a p-type layer, and an active layer between the n-type layer and the p-type layer; a reflective layer on the active LED structure; and a lumiphoric material layer between the reflective layer and the active LED structure, the lumiphoric material layer configured to convert at least a portion of light generated by the active LED structure to a different wavelength. In certain embodiments, a portion of the lumiphoric material layer is arranged on mesa sidewalls of the p-type layer, the active layer, and a portion of the n-type layer. The LED chip may further comprise a passivation layer on the lumiphoric material layer, wherein a portion of the passivation layer is arranged on the portion of the lumiphoric material layer that is on the mesa sidewalls. The LED chip may further comprise: an n-contact electrically coupled to the n-type layer; and a p-contact electrically coupled to the p-type layer; wherein the lumiphoric material layer is arranged between the active LED structure and the p-contact, and the lumiphoric material layer is arranged between the active LED structure and the n-contact. The LED chip may further comprise an n-contact interconnect that extends through an opening formed in the p-type layer, the active layer, and a portion of the n-type layer, wherein the lumiphoric material layer surrounds portions of the n-contact interconnect that reside within the opening. The LED chip may further comprise a current spreading layer on the p-type layer, wherein the current spreading layer is between the p-type layer and the lumiphoric material layer, the current spreading layer forms at least one opening on the p-type layer, and a portion of the lumiphoric material layer extends through the at least one opening. In certain embodiments, the lumiphoric material layer comprises lumiphoric particles in a binder material. In certain embodiments, the lumiphoric particles comprise phosphor particles. In certain embodiments, the lumiphoric particles comprise quantum dots. In certain embodiments, one or more of the lumiphoric particles are entirely encapsulated by the binder material. In certain embodiments, the lumiphoric material layer comprises a first sublayer of lumiphoric particles and a second sublayer on the first sublayer. In certain embodiments, the lumiphoric material layer comprises lumiphoric particles with one or more surface modifiers along outer shells of the lumiphoric particles. The LED chip may further comprise a plurality of reflective layer interconnects that extend through openings of the lumiphoric material layer.

In certain embodiments: the active LED structure is configured to generate light of a first peak wavelength; the lumiphoric material layer is configured to convert a portion of the light of the first peak wavelength to light of a second peak wavelength that is different than the first peak wavelength; and an intensity of the second peak wavelength is less than or equal to 30% of an intensity of the first peak wavelength. In certain embodiments, the lumiphoric material layer is further configured to convert another portion of the light of the first peak wavelength to light of a third peak wavelength, and an intensity of the third peak wavelength is less than or equal to 30% of the intensity of the first peak wavelength. In certain embodiments, the first peak wavelength and the second peak wavelength are in a range from 400 nanometers (nm) to 700 nm. In certain embodiments, the first peak wavelength is in a range from 400 nm to 700nm, and the second peak wavelength is below 400 nm or above 700 nm.

In certain embodiments, the LED chip may further comprise an additional lumiphoric material layer on an opposite side of the active LED structure from the lumiphoric material layer that is between the reflective layer and the active LED structure.

In another aspect, an LED chip comprises: an active LED structure comprising an n-type layer, a p-type layer, and an active layer between the n-type layer and the p-type layer; a first contact electrically coupled to the active LED structure; and a lumiphoric material layer between the contact and the active LED structure, the lumiphoric material layer configured to convert at least a portion of light generated by the active LED structure to a different wavelength. In certain embodiments: the active LED structure is configured to generate light of a first peak wavelength; the lumiphoric material layer is configured to convert a portion of the light of the first peak wavelength to light of a second peak wavelength; and an intensity of the second peak wavelength is less than or equal to 30% of an intensity of the first peak wavelength.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of a light-emitting diode (LED) chip with an internal lumiphoric material layer according to principles of the present disclosure.

FIG. 1B is a plot of an exemplary emission spectrum for the LED chip of FIG. 1A.

FIG. 2A is a cross-sectional view of a portion of the LED chip of FIG. 1A for embodiments where the lumiphoric material layer includes lumiphoric particles within a binder material.

FIG. 2B is a cross-sectional view of a portion of the LED chip of FIG. 1A for alternative embodiments where the lumiphoric material layer includes the lumiphoric particles without the binder material of FIG. 2A.

FIG. 2C is a cross-sectional view of a portion of the LED chip of FIG. 2B for alternative embodiments where the lumiphoric material layer includes a multiple layer structure.

FIG. 3 is a generalized fabrication sequence for providing surface modification to a lumiphoric particle.

FIG. 4A is a cross-sectional view of an LED chip that is similar to the LED chip of FIG. 1A for embodiments where lumiphoric particles of the lumiphoric material layer comprise quantum dots.

FIG. 4B is an expanded view of a portion of the LED chip of FIG. 4A taken from the superimposed dashed-line box of FIG. 4A.

FIG. 5 is a cross-sectional view of a portion of an LED chip that is similar to the LED chip of FIG. 4A but without the lumiphoric particles to illustrate effects of internal light absorption.

FIG. 6 is a cross-sectional view of a portion of the LED chip of FIG. 4A showing how the presence of the lumiphoric material layer decreases internal absorption.

FIG. 7A is a cross-sectional view of an LED chip that is similar to the LED chip of FIG. 4A and where the lumiphoric material layer includes multiple types of lumiphoric particles.

FIG. 7B is an expanded view of a portion of the LED chip of FIG. 7A taken from the superimposed dashed-line box of FIG. 7A.

FIG. 7C is a plot of an exemplary emission spectrum for the LED chip of FIG. 7A.

FIG. 8A is a cross-sectional view of an LED chip that is similar to the LED chip of FIG. 7A and where the lumiphoric material layer includes even more types of lumiphoric particles.

FIG. 8B is an expanded view of a portion of the LED chip of FIG. 8A taken from the superimposed dashed-line box of FIG. 8A.

FIG. 8C is a plot of an exemplary emission spectrum for the LED chip of FIG. 8A.

FIG. 9 is a cross-sectional view of an LED chip that is similar to the LED chip of FIG. 1A for another LED chip structure with a vertical contact orientation.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to arrangements of lumiphoric materials within LED chips. Lumiphoric materials are incorporated or otherwise embedded within LED chips. Embedded lumiphoric materials are provided so that at least some portions of light generated by active LED structures are subject to wavelength conversion before exiting LED chip surfaces. Lumiphoric materials may form dielectric and/or passivation layers between various chip structures, such as between active LED structures and internal reflective layers and/or electrical contacts. Internally converted light propagating within LED chips may pass back through active LED structures with reduced light absorption.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include silicon carbide (SiC), organic semiconductor materials, and other Group III-V systems such as gallium phosphide (GaP), gallium arsenide (GaAs), and related compounds. The active LED structure may be grown on a growth substrate that can include many materials, such as sapphire, SiC, aluminum nitride (AlN), and GaN.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. Other wavelength ranges include a range from 400 nm to about 430 nm and/or a range from 480 nm to 500 nm, among others, or any wavelength in a range from 400 nm to 750 nm. In certain embodiments, the active LED structure may be configured to emit light that is outside the visible spectrum, including infrared (IR) or one or more portions of the ultraviolet (UV) spectrum. The IR spectrum may encompass wavelengths from 700 nm to 1000 nm. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are provided from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate.

LED chips as described herein may be well suited for placement in LED packages that may include one or more elements, such as cover structures with additional lumiphoric materials or phosphors for wavelength conversion, encapsulants, light-altering materials, lenses, and electrical contacts, among others, that are provided with one or more LED chips. Such LED packages may include a support structure or member, such as a submount or a lead frame. A support structure may refer to a structure of an LED package that supports one or more other elements of the LED package, including but not limited to LED chips and cover structures. In certain embodiments, a support structure may include a submount on which an LED chip is mounted. Suitable materials for a submount include, but are not limited to, ceramic materials such as aluminum oxide or alumina, AlN, or organic insulators like polyimide (PI) and polyphthalamide (PPA). In other embodiments a submount may comprise a printed circuit board (PCB), sapphire, Si, or any other suitable material. For PCB embodiments, different PCB types can be used such as standard FR-4 PCB, metal core PCB, or any other type of PCB. In still further embodiments, the support structure may embody a lead frame structure.

Lumiphoric materials (also referred to herein as lumiphors) are positioned to receive and absorb at least some of the light from an LED chip and convert such light to one or more different wavelength spectra according to the characteristic emission from the lumiphoric materials. In this regard, at least one lumiphor receiving at least a portion of the light generated by the LED chip may re-emit light having different peak wavelength than the LED source. An LED chip and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500 Kelvin (K) to 10,000 K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. In still further embodiments, an LED chip may be configured to emit light outside the visible spectrum, such as UV light, and the lumiphoric materials may convert at least a portion of the UV light to visible light. In other embodiments, the LED chip may be configured to emit visible light and lumiphoric materials may be provided that convert at least a portion of the visible light to IR or UV wavelengths.

Lumiphoric materials as described herein may be or include one or more of a phosphor, a scintillator, a lumiphoric ink, a quantum dot material, a day glow tape, and the like. Lumiphoric materials may be provided by any suitable means, for example, dispersal of particles in a host material or an encapsulant material. In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In certain embodiments, one or more lumiphoric materials may be arranged in a substantially uniform manner. In other embodiments, one or more lumiphoric materials may be arranged in a manner that is non-uniform with respect to one or more of material composition, concentration, and thickness. In certain embodiments, the loading percentage of one or more lumiphoric materials may be varied relative to one or more positions of an LED chip. In certain embodiments, one or more lumiphoric materials may be patterned to include one or more stripes, dots, curves, or polygonal shapes. In certain embodiments, multiple lumiphoric materials may be arranged in different discrete regions or discrete layers for an LED chip.

Typical LED chips exhibit narrowband emissions according to bandgaps and/or other arrangements provided by their active LED structures. Lumiphoric materials, which convert portions of these narrowband emissions to other wavelengths, serve to broaden the aggregate emissions of the overall devices. Lumiphoric materials are typically formed on or over LED chips after such LED chips are substantially fabricated. For example, an LED chip may be mounted within a package and lumiphoric materials may be formed thereon, such as by dispensing or spray-coating. In another example, lumiphoric materials may be added to a top surface of a fully fabricated LED chip before mounting within a package.

According to aspects of the present disclosure, lumiphoric materials may be incorporated or otherwise embedded within LED chips during fabrication thereof. In this regard, such LED chips may emit broader emissions and may be used alone or in combination with additional lumiphoric materials provided over top surfaces of the LED chips. In certain embodiments, the embedded lumiphoric materials may provide light with a peak wavelength that is different than both the active LED structure of the LED chip and the additional lumiphoric materials in order to provide further broadened emissions. For example, the emissions of the embedded lumiphoric materials may be configured to fill a portion of an emission spectrum that is between the active LED structure and the additional lumiphoric materials. In other embodiments, embedded lumiphoric materials may be configured to convert portions of visible light from the active LED structure to nonvisible wavelengths, such as IR or UV.

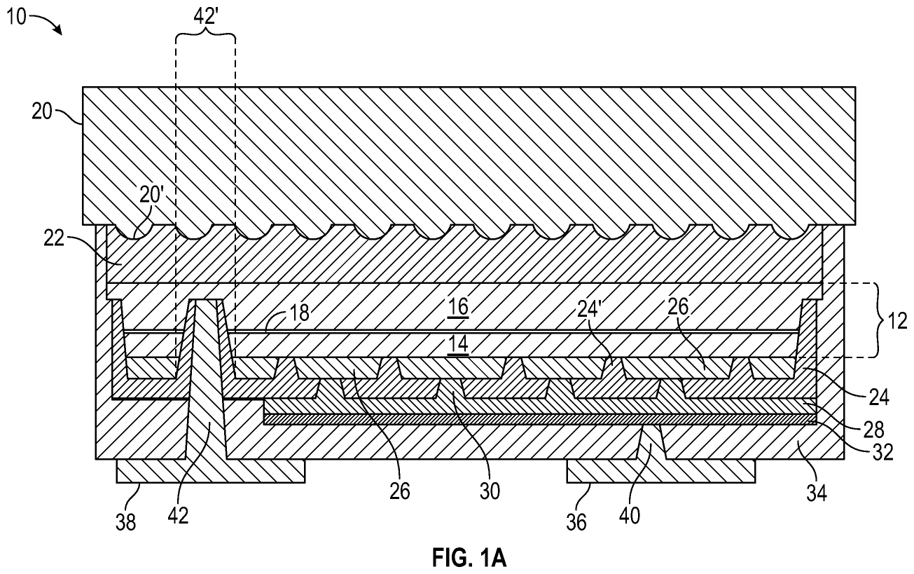

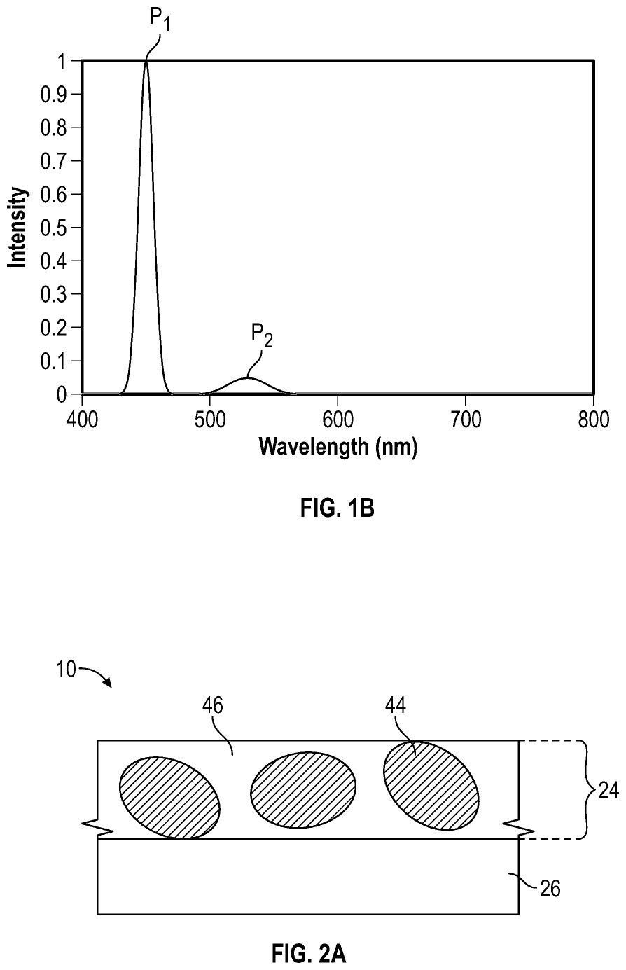

FIG. 1A is a cross-sectional view of an LED chip 10 according to principles of the present disclosure. The LED chip 10 includes an active LED structure 12 comprising a p-type layer 14, an n-type layer 16, and an active layer 18 formed on a substrate 20. In FIG. 1A, the LED chip 10 is illustrated with an orientation for flip-chip mounting. In certain embodiments, one or more buffer layers and/or undoped layers 22 may be provided between the substrate 20 and the active LED structure 12. The substrate 20 may embody a patterned substrate such that a surface 20′ of the substrate 20 closest to the active LED structure 12 is patterned. In certain embodiments, the n-type layer 16 is between the active layer 18 and the substrate 20. In other embodiments, the doping order may be reversed. The substrate 20 can comprise many different materials such as SiC or sapphire and can have one or more surfaces that are shaped, textured, or patterned to enhance light extraction. In certain embodiments, the substrate 20 is light transmissive (preferably transparent) and may include a patterned surface 20′ that is proximate the active LED structure 12 and includes multiple recessed and/or raised features.

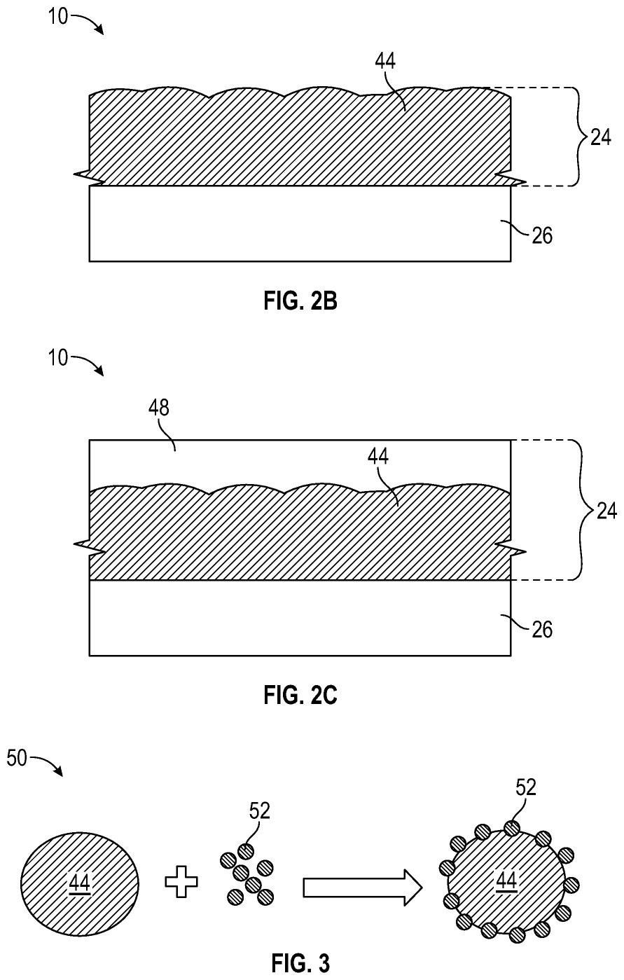

In FIG. 1A, a lumiphoric material layer 24 is provided on portions of the p-type layer 14 with a current spreading layer 26 therebetween. As will be later described in detail for FIGS. 2A to 2C, the lumiphoric material layer 24 may comprise many different materials and in some examples a multiple layer structure. The current spreading layer 26 may embody a layer of conductive material, for example a transparent conductive oxide such as indium tin oxide (ITO) or a metal such as platinum (Pt), although other materials may be used. In certain embodiments, the current spreading layer 26 is formed with a number of openings or even discontinuous regions on the p-type layer 14. This arrangement allows portions 24′ of the lumiphoric material layer 24 to extend through the current spreading layer 26 and contact the p-type layer 14. In this manner, interfaces formed between the p-type layer 14 and the lumiphoric material layer 24 that do not include the current spreading layer 26 may exhibit increased wavelength conversion for light generated by the active LED structure 12. Even though the current spreading layer 26 does not continuously cover the p-type layer 14, the openings or discontinuous regions of the current spreading layer 26 may have small enough lateral dimensions to still suitably spread current along the p-type layer 14. In other arrangements, the current spreading layer 26 could continuously cover the p-type layer 14 without openings. In still further embodiments, the current spreading layer may be omitted.

The LED chip 10 may further include a reflective layer 28 that is on the lumiphoric material layer 24 such that the lumiphoric material layer 24 is arranged between the active LED structure 12 and the reflective layer 28. The reflective layer 28 may include a metal layer that is configured to reflect any light from the active LED structure 12 that may pass through the lumiphoric material layer 24. The reflective layer 28 may comprise many different materials such as Ag, gold (Au), or combinations thereof. Accordingly, the reflective layer 28 may be referred to as a metal reflector layer and/or a metal reflective layer. As illustrated, the reflective layer 28 may include one or more reflective layer interconnects 30 that provide electrically conductive paths through the lumiphoric material layer 24 to the current spreading layer 26. In certain embodiments, the reflective layer interconnects 30 comprise reflective layer vias. In some embodiments, the reflective layer interconnects 30 comprise the same material as the reflective layer 28 and are formed at the same time as the reflective layer 28. In other embodiments, the reflective layer interconnects 30 may comprise a different material than the reflective layer 28.

The LED chip 10 may also comprise a barrier layer 32 on a side of the reflective layer 28 opposite the lumiphoric material layer 24 to prevent migration of the reflective layer 28 material, such as Ag, to other layers. Preventing this migration helps the LED chip 10 maintain efficient operation through its lifetime. The barrier layer 32 may comprise an electrically conductive material, with suitable materials including but not limited to sputtered Ti/Pt followed by evaporated Au bulk material or sputtered Ti/Ni followed by an evaporated Ti/Au bulk material.

A passivation layer 34 may be included on the barrier layer 32 as well as any portions of the reflective layer 28 that may be uncovered by the barrier layer 32. The passivation layer 34 may further be arranged on portions of the lumiphoric material layer 24 that are uncovered by the reflective layer 28. The passivation layer 34 protects and provides electrical insulation for the LED chip 10 and can comprise many different materials, such as a dielectric material. In certain embodiments, the passivation layer 34 is a single layer, and in other embodiments, the passivation layer 34 comprises a plurality of layers. A suitable material for the passivation layer 34 includes but is not limited to SiN, SiNx, and/or Si₃N₄. As illustrated, the lumiphoric material layer 24 may bound perimeter and/or mesa sidewall portions of the active LED structure 12, including mesa sidewalls of the p-type layer 14, the active layer 18, and the n-type layer 16 along a perimeter of the LED chip 10. Furthermore, the passivation layer 34 may be arranged to also bound perimeter portions of the active LED structure 12 where the passivation layer 34 extends to the substrate 20. In this manner, portions of the lumiphoric material layer 24 may be arranged between portions of the passivation layer 34 and sidewalls of the active LED structure 12 for enhanced wavelength conversion along perimeter edges of active LED structure 12.

In FIG. 1A, the LED chip 10 comprises a p-contact 36 and an n-contact 38 that are arranged on the passivation layer 34 and are configured to provide electrical connections with the active LED structure 12. The p-contact 36, which may also be referred to as an anode contact, may comprise one or more p-contact interconnects 40 that extend through the passivation layer 34 to the barrier layer 32 or the reflective layer 28 to provide an electrical path to the p-type layer 14. In certain embodiments, the one or more p-contact interconnects 40 comprise one or more p-contact vias. The n-contact 38, which may also be referred to as a cathode contact, is electrically coupled to the n-type layer 16 by way of one or more n-contact interconnects 42 that extend through the passivation layer 34, the barrier layer 32, the lumiphoric material layer 24, the reflective layer 28, the p-type layer 14, and the active layer 18. In certain embodiments, the one or more n-contact interconnects 42 may be referred to as one or more n-contact vias. Openings 42′ for the n-contact interconnects 42 may be formed in a separate etching step than etching along the perimeter of the LED chip 10 where the passivation layer 34 bounds the active LED structure 12.

In operation, a signal applied across the p-contact 36 and the n-contact 38 is conducted to the p-type layer 14 and the n-type layer 16, causing the LED chip 10 to emit light from the active layer 18. The p-contact 36 and the n-contact 38 can comprise many different materials such as Au, copper (Cu), nickel (Ni), In, Al, Ag, tin (Sn), Pt, or combinations thereof. In still other embodiments, the p-contact 36 and the n-contact 38 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. As described above, the LED chip 10 is arranged for flip-chip mounting and the p-contact 36 and n-contact 38 are configured to be mounted or bonded to a surface, such as a printed circuit board. While FIG. 1A is described in the context of a flip-chip structure, the principles disclosed for one or more of the current spreading layer 26, the lumiphoric material layer 24, the reflective layer 28, and the barrier layer 32 are readily applicable to other chip structures. For illustrative purposes, FIG. 1A is shown with a single n-contact interconnect 42. In practice, the LED chip 10 may include multiple n-contact interconnects 42 spaced apart in an array pattern across the active LED structure 12.

As illustrated in FIG. 1A, the lumiphoric material layer 24 is essentially embedded within the LED chip 10. In this manner, the LED chip 10 may be pre-configured to provide additional emission spectrum beyond just the narrow band emissions of the active LED structure 12. As illustrated, the lumiphoric material layer 24 may be arranged between the reflective layer 28 and the active LED structure 12. Accordingly, at least a portion of downward propagating light from the active layer 18 and toward the reflective layer 28 may be subject to wavelength conversion before such light is reflected back and ultimately escapes the LED chip 10 through the substrate 20. In this regard, a combination of light having a first peak wavelength generated by the active LED structure 12 and light having a second peak wavelength that is generated by wavelength conversion may concurrently exit the substrate 20. As described above, the lumiphoric material layer 24 may further extend on mesa sidewalls of the p-type layer 14, the active layer 18, and a portion of the n-type layer 16 proximate perimeter edges of the active LED structure 12. In this regard, at least a portion of laterally propagating light from the active LED structure 12 may also be subject to wavelength conversion.

In the flip-chip orientation of FIG. 1A, the lumiphoric material layer 24 may also be arranged between the active LED structure 12 and both the p-contact 36 and the n-contact 38. As further illustrated, peripheral edges of the portion of the n-contact interconnect 42 that extends through the active LED structure 12 may be laterally surrounded by the lumiphoric material layer 24. Accordingly, downward and/or laterally propagating light in a direction toward the n-contact interconnect 42 may be subject to wavelength conversion before reaching the n-contact interconnect 42. Light scattering may also occur within the lumiphoric material layer 24 such that at least a portion of light, converted and/or unconverted, may be scattered and redirected away from the n-contact interconnect 42. Light scattering effectively increases the likelihood of light propagating along escape cones in order to exit the LED chip 10 in a desired emission direction, such as through the substrate 20. In this regard, light scattering may increase brightness and/or efficiency of the LED chip 10 by reducing light loss due to absorption at the n-contact interconnect 42. Similar increases in brightness and/or efficiency may be attributed to light-scattering before light reaches the p-contact 36 and/or the n-contact 40, or even another surface on which the LED chip 10 is flip-chip mounted.

The lumiphoric material layer 24 may be formed by various techniques during the fabrication sequence for the LED chip 10. By incorporating the lumiphoric material layer 24 before the final structure of the LED chip 10 is complete, the lumiphoric material layer 24 is effectively embedded within the LED chip 10 to provide the various advantages described above. Exemplary techniques for forming the lumiphoric material layer 24 include sputter deposition with laser annealing, electrospray, electromagnetic brush coating, powder coating, spin coating, and/or electrophoretic deposition. The lumiphoric material layer 24 may be formed of a single layer or a multiple layer structure.

FIG. 1B is a plot of an exemplary emission spectrum for the LED chip 10 of FIG. 1A. In this example, the active LED structure 12 of FIG. 1A is configured to emit a first peak wavelength P₁ that is blue. The lumiphoric material layer 24 is configured to convert a portion of the first peak wavelength P₁ to a second peak wavelength P₂ that is different, such as green and/or yellow. In certain embodiments, the amount of wavelength conversion provided by the lumiphoric material layer 24 is such that a majority of emissions from the LED chip 10 are at the first peak wavelength P₁. In this manner, the LED chip 10 may be implemented in place of conventional blue LED chips while also providing additional emissions for enhanced optical characteristics, such as color rendering and/or color quality. For example, the second peak wavelength P₂ may have an intensity that is less than or equal to 30%, or less than or equal to 20%, or less than or equal to 10% of the intensity of the first peak wavelength P₁. For applications where additional intensity of the second peak wavelength P₂ is desired, the concentration of lumiphoric materials and/or thickness of the lumiphoric material layer 24 may be increased.

FIGS. 2A to 2C are cross-sectional views of a portion of the LED chip 10 of FIG. 1A showing different arrangements of an interface between the lumiphoric material layer 24 and the current spreading layer 26. While FIGS. 2A to 2C are illustrated in the context of the current spreading layer 26, the principles disclosed are equally applicable to portions of the LED chip 10 where the lumiphoric material layer 24 forms an interface with the p-type layer 14, or for embodiments where the current spreading layer 26 is omitted. In this regard, such alternatives would be represented by replacing the current spreading layer 26 of FIGS. 2A to 2C with the p-type layer 14.

FIG. 2A is a cross-sectional view of a portion of the LED chip 10 of FIG. 1A for embodiments where the lumiphoric material layer 24 includes lumiphoric particles 44 within a binder material 46. In certain embodiments, the lumiphoric material layer 24 may be formed on the LED chip 10 followed by curing of the binder material 46. The lumiphoric particles 44 may include phosphor particles and/or quantum dots. In certain embodiments, the lumiphoric particles 44 may include mixtures of different types of lumiphoric particles 44 that provide multiple different wavelengths. In certain embodiments, the binder material 46 comprises a dielectric material, with some embodiments comprising silicon dioxide (SiO₂) and/or silicon nitride (SiN). Specific materials for the binder material 46 may be selected based on the type of lumiphoric particles 44. For example, in the context of phosphor particles, the binder material 46 may comprise any of SiN, SiNx, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. In the context of quantum dots, the binder material 46 may comprise SiN, SiNx, Si₃N₄, TiO₂, or Al₂O₃, among others. In certain embodiments, the binder material 46 comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. The lumiphoric material layer 24 can have different thicknesses depending on the type of lumiphoric particles 44 used. For phosphor particles, the lumiphoric material layer 24 may have a thickness that corresponds to an average particle size of the phosphor particles or greater to ensure suitable coverage, such as at least 1 micron (μm), or in a range from 1 μm to 10 μm, or in a range from 1 μm to 5 μm. In the context of quantum dots with particle sizes in the range of 1 to 15 nm, the lumiphoric material layer 24 may have a reduced thickness, such as in a range from 200 nm to 700 nm.

FIG. 2B is a cross-sectional view of a portion of the LED chip 10 of FIG. 1A for alternative embodiments where the lumiphoric material layer 24 includes the lumiphoric particles 44 without the binder material 46 of FIG. 2A. In this manner, the lumiphoric particles 44 may be directly coated without the binder material 46 and corresponding curing step.

FIG. 2C is a cross-sectional view of a portion of the LED chip 10 of FIG. 2B for alternative embodiments where the lumiphoric material layer 24 includes a multiple layer structure. In certain embodiments, the lumiphoric particles 44 form a first sublayer, and a second sublayer 48 is formed on the lumiphoric particles 44. The second sublayer 48 may be devoid of the lumiphoric particles 44 to effectively provide encapsulation. The second sublayer 48 may include any of the materials for the binder material 46 of FIG. 2A. In other embodiments, the second sublayer 48 may comprise a second layer of lumiphoric particles that provide a different wavelength than the first sublayer.

FIG. 3 is a generalized fabrication sequence for providing surface modification to a lumiphoric particle 44. In certain embodiments, any of the lumiphoric particles 44 described herein may include surface modification that provides one or more of improved protection, improved index of refraction grading, and/or enhanced bonding within the LED chip. As illustrated, a surface modifier 52 may be added to the lumiphoric particle 44 such that the surface modifier 52 effectively changes one or more characteristics of an outer shell of the lumiphoric particle 44. Multiple surface modifiers 52 may be formed along the outer shell as illustrated. In other embodiments, the surface modifiers 52 may form a continuous coating along the outer shell of the lumiphoric particle 44. In certain embodiments, the surface modifier 52 may reduce unwanted oxidation of the lumiphoric particle 44 and/or enhance bonding of the lumiphoric particle 44 to surfaces within the LED chip 10 of FIG. 1A. Enhanced bonding may also be provided between the lumiphoric particle 44 and the binder material 46 of FIG. 2A. In certain embodiments, the surface modifier 52 may include one or more of silanes (e.g., tetraethyl orthosilicate, tetramethyl orthosilicate, (3-Aminopropyl)triethoxysilane, etc.), carboxylates, silica, oxides, and alumina, among others.

The surface modifier 52 may be formed on the lumiphoric particle 44 by a number of techniques. For example, the lumiphoric particle 44 may be contacted with a solution or sol-gel containing the surface modifier 52, followed by a drying and/or heating step. The surface modifier 52 may be applied via dip-coating, spread-coating, spray coating, spin coating, brushing, absorption, rolling, and electrodeposition. The coated lumiphoric particle 44 may be subjected to vacuum drying, photocuring, and/or thermal curing. The surface modifier 52 may be formed by passivating surfaces thereof, such as oxidation of lumiphoric particle 44. Still other coatings may be achieved by chemical reactions of precursor materials with materials of the lumiphoric particle 44. In various embodiments, coating steps may be performed once or repeated a number of times to achieve desired thicknesses and/or coverage.

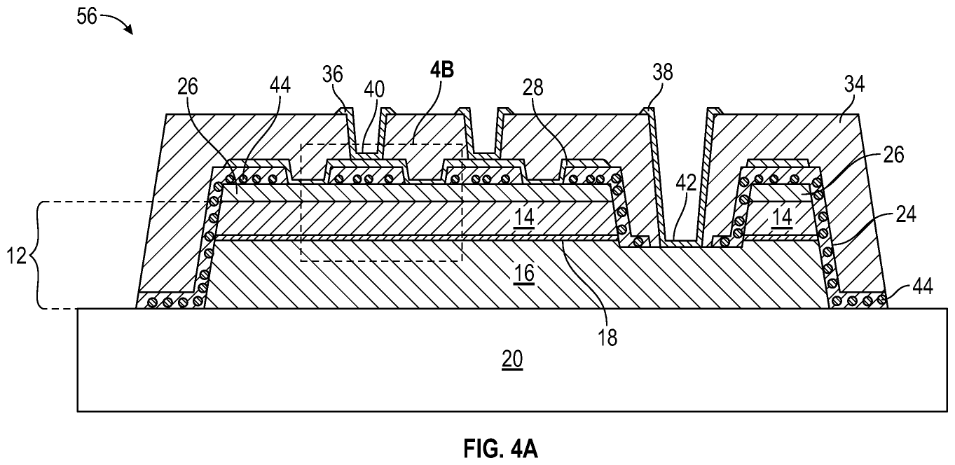

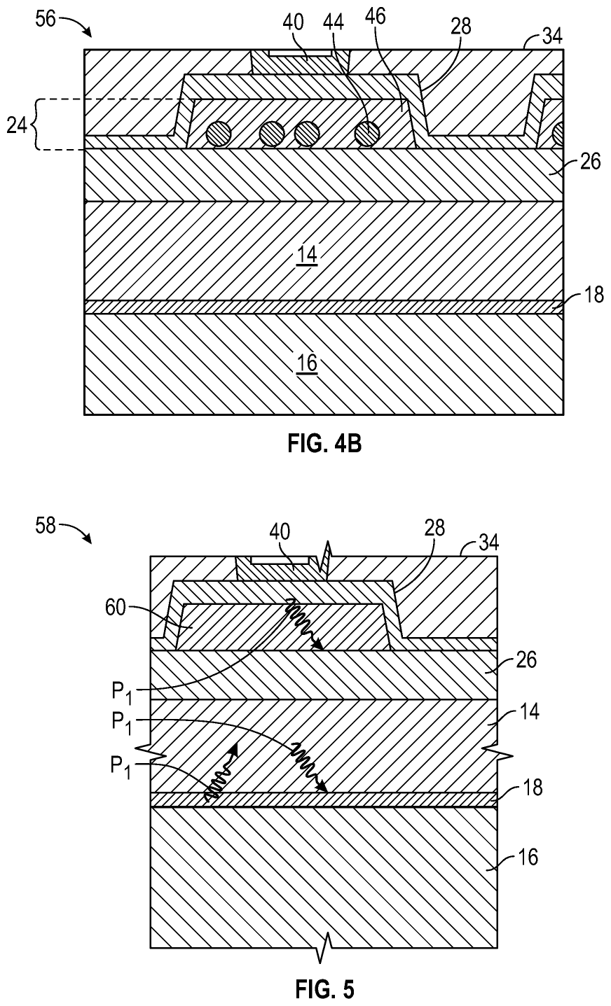

FIG. 4A is a cross-sectional view of an LED chip 56 that is similar to the LED chip 10 of FIG. 1A for embodiments where lumiphoric particles 44 of the lumiphoric material layer 24 comprise quantum dots. In FIG. 4A, the LED chip 56 is illustrated with an orientation before being inverted for flip-chip mounting. FIG. 4B is an expanded view of a portion of the LED chip 56 taken from the superimposed dashed-line box of FIG. 4A. Quantum dots typically have smaller sizes than phosphor particles. In this regard, quantum dots may readily be incorporated within one or more layers of the LED chip 56, such as various dielectric layers, without requiring increased thickness for such layers. For example, quantum dots may range from 2 nm to 50 nm. In this manner, when the lumiphoric particles 44 comprise quantum dots, the binder material 46 of the lumiphoric material layer 24 may entirely encapsulate one or more of the lumiphoric particles 44. Such an arrangement of entirely encapsulated lumiphoric particles 44 may extend along mesa sidewalls of the active LED structure 12. In other embodiments, one or more of the lumiphoric particles 44 may settle and contact the current spreading layer 26 and/or p-type layer 14. In such an arrangement, the one or more of the lumiphoric particles 44 may be partially encapsulated by the binder material 46.

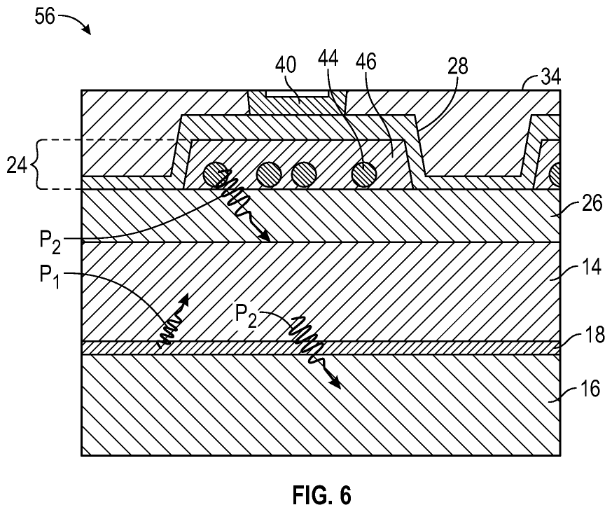

According to principles of the present disclosure, LED chips with embedded and/or integrated lumiphoric materials may exhibit increased efficiency. For example, by internally converting portions of light to other wavelengths, such converted light may more readily pass through the LED chip with reduced internal absorption. For illustrative purposes in showing internal absorption improvements, FIGS. 5 and 6 respectively illustrate light behavior in LED chips with and without embedded and/or integrated lumiphoric materials.

FIG. 5 is a cross-sectional view of a portion of an LED chip 58 that is similar to the LED chip 56 of FIG. 4 but without the lumiphoric particles 44 to illustrate effects of internal light absorption. As with FIG. 4, the orientation of FIG. 5 is from the perspective before the LED chip 58 is inverted for flip-chip mounting. In this regard, the intended direction of light is down through the n-type layer 16. For the LED chip 58, the lumiphoric material layer 24 of FIG. 4 is replaced with a dielectric layer 60 that is devoid of any lumiphoric materials or particles. In operation, the active layer 18 may generate light of the first peak wavelength P₁. Certain portions of the light of the first peak wavelength P₁ will propagate away from the intended emission direction and through various portions of the LED chip 58. Such light may be reflected by the reflective layer 28 back toward the intended emission direction. Accordingly, this light may pass back toward the active layer 18. Since this light is at the same first peak wavelength P₁, a portion of it may be lost to absorption in the active layer 18.

FIG. 6 is a cross-sectional view of a portion of LED chip 56 of FIG. 4 showing how the presence of the lumiphoric material layer 24 decreases internal absorption. In this regard, the LED chip 56 is similar to the LED chip 58 of FIG. 5 but includes the lumiphoric material layer 24. As illustrated in FIG. 6, a portion of the light of the first peak wavelength P₁ is converted to light of the second peak wavelength P₂ before being redirected back toward the intended emission direction. Since the second peak wavelength P₂ is at a different wavelength when interacting with the active layer 18, the second peak wavelength P₂ may more easily pass through with reduced absorption. In this regard, the LED chip 56 may exhibit increased efficiency.

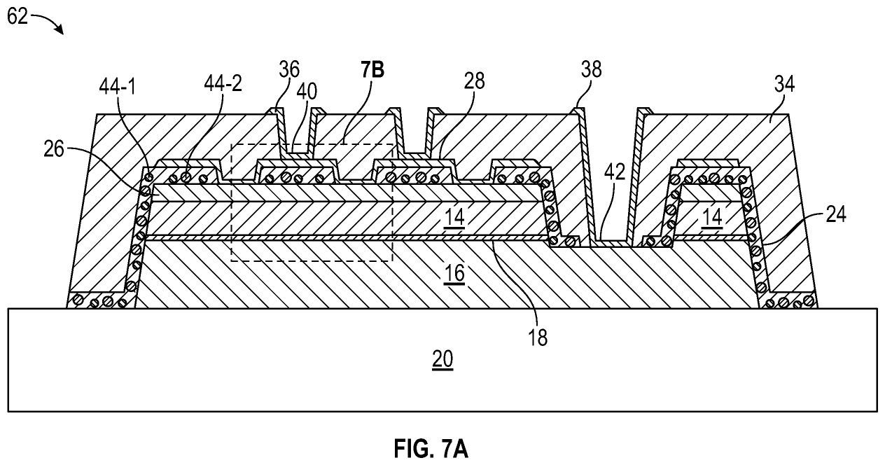

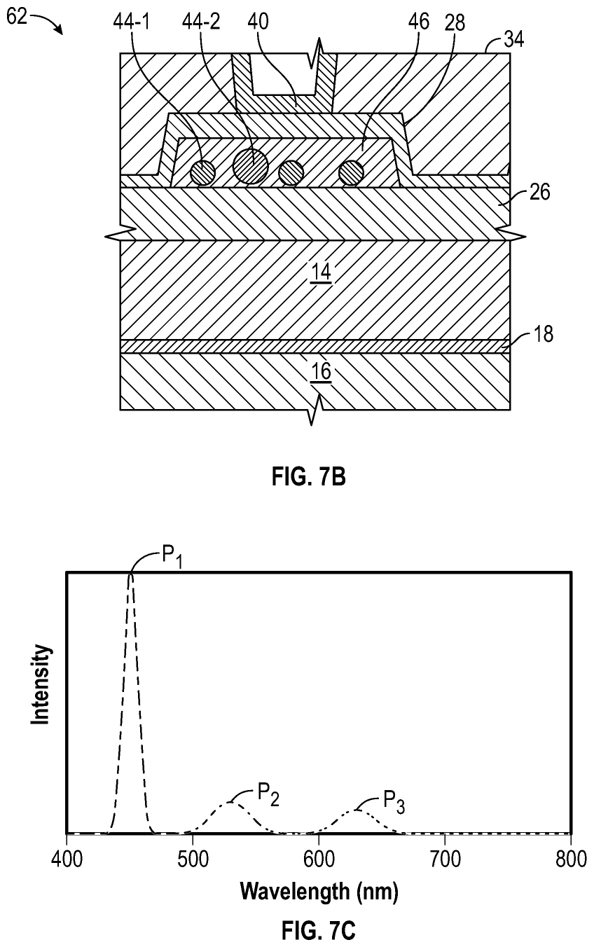

FIG. 7A is a cross-sectional view of an LED chip 62 that is similar to the LED chip 56 of FIG. 4A and where the lumiphoric material layer 24 includes multiple types of lumiphoric particles 44-1, 44-2. FIG. 7B is an expanded view of a portion of the LED chip 62 taken from the superimposed dashed-line box of FIG. 7A. As illustrated, the lumiphoric material layer 24 includes first lumiphoric particles 44-1 and second lumiphoric particles 44-2. The second lumiphoric particles 44-2 are configured to provide a different wavelength than the first lumiphoric particles 44-1. In this regard, principles of the present disclosure may provide the ability for aggregate emissions from the LED chip 62 to have at least two different peak wavelengths beyond the peak wavelength generated by the active layer 18.

FIG. 7C is a plot of an exemplary emission spectrum for the LED chip 62 of FIG. 7A. In this example, the active layer 18 of FIG. 7A is configured to emit the first peak wavelength P₁ that is blue. The first lumiphoric particles 44-1 are configured to convert a portion of the first peak wavelength P₁ to the second peak wavelength P₂ that is different, such as green and/or yellow. The second lumiphoric particles 44-2 are configured to convert a portion of the first peak wavelength P₁ to the third peak wavelength P₃ that is different than both the first peak wavelength P₁ and the second peak wavelength P₂. For example, the third peak wavelength P₃ may provide a red color. In certain embodiments, the second peak wavelength P₂ and the third peak wavelength P₃ may have respective intensities that are less than or equal to 30%, or less than or equal to 20%, or less than or equal to 10% of the intensity of the first peak wavelength P₁. For applications where additional intensity of the second peak wavelength P₂ and/or the third peak wavelength P₃ is desired, the concentration of lumiphoric particles 44-1, 44-2 and/or a thickness of the lumiphoric material layer 24 may be increased.

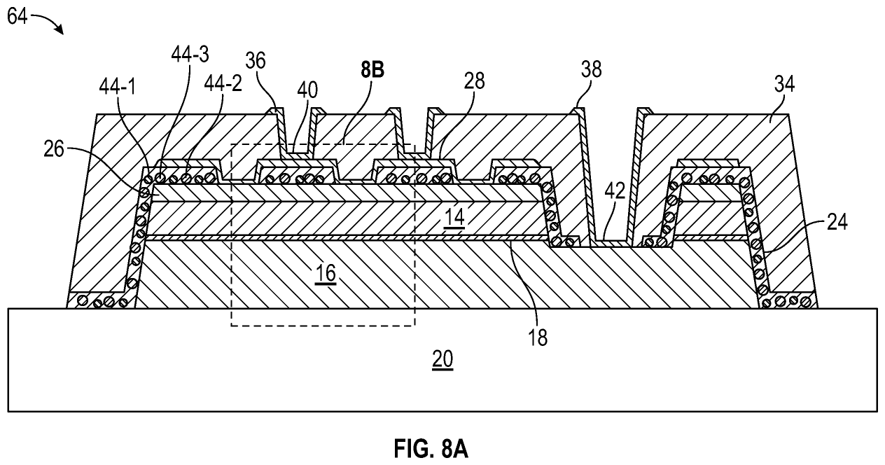

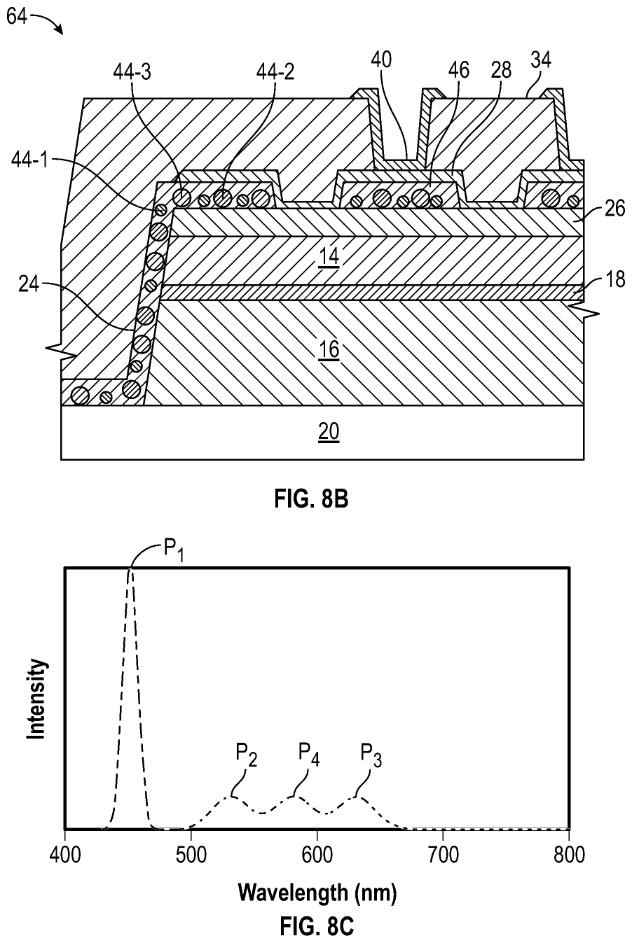

FIG. 8A is a cross-sectional view of an LED chip 64 that is similar to the LED chip 62 of FIG. 7A and where the lumiphoric material layer 24 includes even more types of lumiphoric particles 44-1 to 44-3. FIG. 8B is an expanded view of a portion of the LED chip 64 taken from the superimposed dashed-line box of FIG. 8A. As illustrated, the lumiphoric material layer 24 includes first lumiphoric particles 44-1, second lumiphoric particles 44-2, and third lumiphoric particles 44-2. The second lumiphoric particles 44-2 are configured to provide a different wavelength than the first lumiphoric particles 44-1. The third lumiphoric particles 44-3 are configured to provide a different wavelength than both the first lumiphoric particles 44-1 and the second lumiphoric particles 44-2. In this regard, principles of the present disclosure may provide the ability for aggregate emissions from the LED chip 64 to have at least three different peak wavelengths beyond the peak wavelength generated by the active layer 18.

FIG. 8C is a plot of an exemplary emission spectrum for the LED chip 64 of FIG. 8A. In this example, the active layer 18 of FIG. 8A is configured to emit the first peak wavelength P₁ that is blue. The first lumiphoric particles 44-1 are configured to convert a portion of the first peak wavelength P₁ to the second peak wavelength P₂ that is green, the second lumiphoric particles 44-2 are configured to convert a portion of the first peak wavelength P₁ to the third peak wavelength P₃ that is a red, and the third lumiphoric particles 44-3 are configured to convert a portion of the first peak wavelength P₁ to a fourth peak wavelength P₄ that is a yellow. As with other embodiments, the second peak wavelength P₂, the third peak wavelength P₃, and the fourth peak wavelength P₄ may have respective intensities that are less than or equal to 30%, or less than or equal to 20%, or less than or equal to 10% of the intensity of the first peak wavelength P₁. In other applications where additional intensity from wavelength conversion is desired, the concentration of lumiphoric particles 44-1 to 44-3 and/or a thickness of the lumiphoric material layer 24 may be increased.

While the previous embodiments are described in the context of flip-chip configurations, the principles of the present disclosure are also applicable to other LED chip configurations.

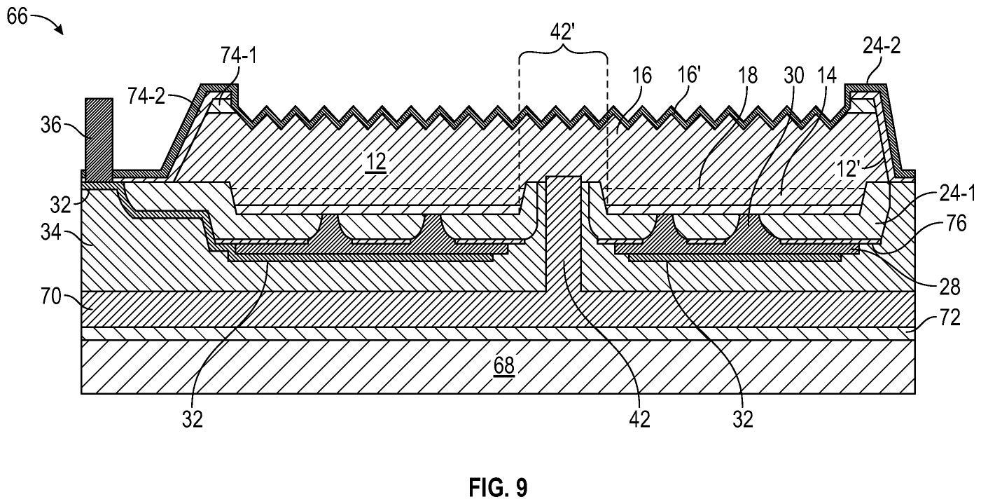

FIG. 9 is a cross-sectional view of an LED chip 66 that is similar to the LED chip 10 of FIG. 1A for another LED chip structure. In FIG. 9, the active LED structure 12 is formed on and supported by a carrier submount 68 that may be made of many different materials, with a suitable material being silicon or doped silicon. In certain embodiments, the carrier submount 68 comprises an electrically conductive material such that the carrier submount 68 is part of electrically conductive connections to the active LED structure 12. As such, the carrier submount 68 and/or another metal layer on a bottom side of the carrier submount 68 may form the n-contact for the active LED structure 12. An n-contact metal layer 70 may be arranged on the passivation layer 34 across the LED chip 10 such that the n-contact metal layer 70 is electrically coupled with the n-contact interconnect 42. The p-contact 36 is provided on a top side of the active LED structure 12. In this manner, the LED chip 66 may be referred to as having a vertical contact structure. In certain embodiments, the barrier layer 32 is arranged to laterally extend beyond portions of the active LED structure 12, or a peripheral border of the active LED structure 12, in order to provide an electrical connection with the p-contact 36. In other embodiments, the polarity may be reversed such that the p-contact 36 is replaced with an n-contact that is electrically coupled to the n-type layer 16 and electrical connections to the p-type layer 14 are made through the carrier submount 68.

In FIG. 9, the p-type layer 14 is arranged between the active layer 18 and the carrier submount 68 such that the p-type layer 14 is closer to the carrier submount 68 than the n-type layer 16. The active LED structure 12 may initially be formed by epitaxially growing or depositing the n-type layer 16, the active layer 18, and the p-type layer 14 sequentially on a growth substrate (e.g., the substrate 20 of FIG. 1A). The active LED structure 12 may then be flipped and bonded to the carrier submount 68 by way of one or more bond metals 72 and the growth substrate is removed. In this manner, a top surface 16′ of the n-type layer 16 forms a primary light-extracting face of the LED chip 66. In certain embodiments, the top surface 16′ may comprise a textured or patterned surface for improving light extraction. In other embodiments, the doping order may be reversed such that the n-type layer 16 is arranged between the active layer 18 and the carrier submount 68. One or more top passivation layers 74-1, 74-2 may be provided on one or more top or side surfaces of the n-type layer 16 for additional electrical insulation. In FIG. 9, the top passivation layer 74-2 is arranged to cover mesa sidewalls 12′ of the active LED structure 12. The top passivation layers 74-1, 74-2 may comprise separate layers or a continuous layer of dielectric material, such as silicon nitride.

As illustrated, the LED chip 66 may include a first lumiphoric material layer 24-1 arranged in a similar manner as the lumiphoric material layer 24 of FIG. 1A. For example, the first lumiphoric material layer 24-1 is embedded within the LED chip 66 between the active LED structure 12 and the reflective layer 28. The LED chip 66 may further include a second lumiphoric material layer 24-2 that is arranged on a top side of the active LED structure 12 such that the active LED structure 12 is between the two lumiphoric material layers 24-1, 24-2. In a similar manner as the first lumiphoric material layer 24-1, the second lumiphoric material layer 24-2 may be incorporated within one or more dielectric and/or passivation layers of the LED chip 66. In certain embodiments, the second lumiphoric material layer 24-2 may conformally cover the top surface 16′ and associated texturing and/or patterning. In still further embodiments, any of the top passivation layers 74-1, 74-2 may also form lumiphoric material layers as described herein.

Certain embodiments may also comprise an adhesion layer 76 that is positioned at one or more interfaces between the reflective layer 28 and the first lumiphoric material layer 24-1 to promote improved adhesion therebetween. Many different materials can be used for the adhesion layer 76, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlₓO_{y}. In certain embodiments, the adhesion layer comprises AlₓO_{y}, where 1≤x≤4 and 1≤y≤6. In certain embodiments, the adhesion layer comprises AlₓO_{y}, where x=2 and y=3, or Al₂O₃. The adhesion layer 76 may be deposited by electron beam deposition that may provide a smooth, dense, and continuous layer without notable variations in surface morphology. The adhesion layer 76 may also be deposited by sputtering, chemical vapor deposition, or plasma enhanced chemical vapor deposition. The adhesion layer 76 as described for FIG. 9 may also be implemented between the reflective layer 28 and the lumiphoric material layer 24 of any of the previous embodiments, including FIGS. 1A, 4A, 4B, 6, 7A, 7B, 8A, and 8B.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active layer between the n-type layer and the p-type layer;
a reflective layer on the active LED structure; and
a lumiphoric material layer between the reflective layer and the active LED structure, the lumiphoric material layer configured to convert at least a portion of light generated by the active LED structure to a different wavelength.

2. The LED chip of claim 1, wherein a portion of the lumiphoric material layer is arranged on mesa sidewalls of the p-type layer, the active layer, and a portion of the n-type layer.

3. The LED chip of claim 2, further comprising a passivation layer on the lumiphoric material layer, wherein a portion of the passivation layer is arranged on the portion of the lumiphoric material layer that is on the mesa sidewalls.

4. The LED chip of claim 1, further comprising:
an n-contact electrically coupled to the n-type layer; and
a p-contact electrically coupled to the p-type layer;
wherein the lumiphoric material layer is arranged between the active LED structure and the p-contact, and the lumiphoric material layer is arranged between the active LED structure and the n-contact.

5. The LED chip of claim 4, further comprising an n-contact interconnect that extends through an opening formed in the p-type layer, the active layer, and a portion of the n-type layer, wherein the lumiphoric material layer surrounds portions of the n-contact interconnect that reside within the opening.

6. The LED chip of claim 1, further comprising a current spreading layer on the p-type layer, wherein the current spreading layer is between the p-type layer and the lumiphoric material layer, the current spreading layer forms at least one opening on the p-type layer, and a portion of the lumiphoric material layer extends through the at least one opening.

7. The LED chip of claim 1, wherein the lumiphoric material layer comprises lumiphoric particles in a binder material.

8. The LED chip of claim 7, wherein the lumiphoric particles comprise phosphor particles.

9. The LED chip of claim 7, wherein the lumiphoric particles comprise quantum dots.

10. The LED chip of claim 7, wherein one or more of the lumiphoric particles are entirely encapsulated by the binder material.

11. The LED chip of claim 1, wherein the lumiphoric material layer comprises a first sublayer of lumiphoric particles and a second sublayer on the first sublayer.

12. The LED chip of claim 1, wherein the lumiphoric material layer comprises lumiphoric particles with one or more surface modifiers along outer shells of the lumiphoric particles.

13. The LED chip of claim 1, further comprising a plurality of reflective layer interconnects that extend through openings of the lumiphoric material layer.

14. The LED chip of claim 1, wherein:
the active LED structure is configured to generate light of a first peak wavelength;
the lumiphoric material layer is configured to convert a portion of the light of the first peak wavelength to light of a second peak wavelength that is different than the first peak wavelength; and
an intensity of the second peak wavelength is less than or equal to 30% of an intensity of the first peak wavelength.

15. The LED chip of claim 14, wherein the lumiphoric material layer is further configured to convert another portion of the light of the first peak wavelength to light of a third peak wavelength, and an intensity of the third peak wavelength is less than or equal to 30% of the intensity of the first peak wavelength.

16. The LED chip of claim 14, wherein the first peak wavelength and the second peak wavelength are in a range from 400 nanometers (nm) to 700 nm.

17. The LED chip of claim 14, wherein the first peak wavelength is in a range from 400 nm to 700 nm, and the second peak wavelength is below 400 nm or above 700 nm.

18. The LED chip of claim 1, further comprising an additional lumiphoric material layer on an opposite side of the active LED structure from the lumiphoric material layer that is between the reflective layer and the active LED structure.

19. A light-emitting diode (LED) chip, comprising:
an active LED structure comprising an n-type layer, a p-type layer, and an active layer between the n-type layer and the p-type layer;
a first contact electrically coupled to the active LED structure; and
a lumiphoric material layer between the contact and the active LED structure, the lumiphoric material layer configured to convert at least a portion of light generated by the active LED structure to a different wavelength.

20. The LED chip of claim 19, wherein:
the active LED structure is configured to generate light of a first peak wavelength;
the lumiphoric material layer is configured to convert a portion of the light of the first peak wavelength to light of a second peak wavelength; and
an intensity of the second peak wavelength is less than or equal to 30% of an intensity of the first peak wavelength.
